(19) United States
(12) Patent Application Publication
(10) Pub. No.: US 2026/0328826 A1
(43) Pub. Date: Oct. 22, 2026

(54) DETECTION APPARATUS INCLUDING ELECTRODE

(71) Applicant: Samsung Electronics Co., Ltd., Suwon-si (KR)

(72) Inventors: Ryuju Sato, Yokohama-shi (JP); Meehyun Lim, Suwon-si (KR); Daehoon Han, Suwon-si (KR)

(73) Assignee: Samsung Electronics Co., Ltd., Suwon-si (KR)

(21) Appl. No.: 19/429,161

(22) Filed: Dec. 22, 2025

(30) Foreign Application Priority Data
Apr. 21, 2025 (JP) 2025-069273
Aug. 19, 2025 (KR) 10-2025-0114750

(51) Int. Cl. G01R 29/12

(52) U.S. Cl. CPC G01R 29/12

(57) ABSTRACT

A detection apparatus includes an electro-optical crystal including a first surface opposing the object and a second surface opposing the object with the first surface therebetween, the electro-optical crystal having a refractive index changing according to the electric field, a light source unit configured to irradiate light onto the electro-optical crystal, a reflection unit provided between the first surface of the electro-optical crystal and the object, the reflection unit configured to reflect light transmitted through the electro-optical crystal, a detection unit configured to detect light reflected by the reflection unit, and an electrode covering a portion of the second surface of the electro-optical crystal.

### CROSS-REFERENCE TO RELATED APPLICATIONS

This present application claims priority to and the benefit under 35 U.S.C. § 119(a)-(d) of Japanese Patent Application No. 2025-069273, filed on Apr. 21, 2025, in the Japanese Patent Office, and Korean Patent Application No. 10-2025-0114750, filed on Aug. 19, 2025, in the Korean Intellectual Property Office, the entire disclosure of which is incorporated herein by reference.

### FIELD

The disclosure relates to a detection apparatus and a detection method.

### BACKGROUND

In an electro-optical probe (EOP) method, an electric field generated by an object may be detected. The EOP method may be used, for example, in an inspection process of a semiconductor device.

In the EOP method, an electro-optical crystal may be used. The electro-optical crystal may be disposed so as to oppose an inspection object such as a semiconductor device (hereinafter referred to as an object). In the electro-optical crystal, a phenomenon in which a refractive index is changed under the influence of an electric field generated by the object, that is, an electro-optical effect, may occur. In the EOP method, the electric field generated by the object may be detected using the electro-optical effect.

### SUMMARY

In an electro-optical probe (EOP) method, it may be desirable to increase a signal amount based on an electro-optical effect.

The disclosure is to provide a detection apparatus and a detection method capable of increasing a signal amount based on an electro-optical effect.

According to aspects of the disclosure, there is provided a detection apparatus for detecting an electric field generated by an object, the detection apparatus including an electro-optical crystal including a first surface opposing the object and a second surface opposing the object with the first surface therebetween, the electro-optical crystal having a refractive index changing according to the electric field, a light source unit configured to irradiate light onto the electro-optical crystal, a reflection unit between the first surface of the electro-optical crystal and the object, the reflection unit configured to reflect light transmitted through the electro-optical crystal, a detection unit configured to detect light reflected by the reflection unit, and an electrode covering a portion of the second surface of the electro-optical crystal.

The electrode may include a plurality of first conductive films. The plurality of first conductive films may be disposed with a gap interposed therebetween in a first direction, substantially parallel to the second surface.

Each of the plurality of first conductive films may extend in a second direction, intersecting the first direction.

The electrode may further include a plurality of second conductive films extending substantially in the first direction. The plurality of second conductive films may be disposed with a gap interposed therebetween in the second direction.

The electrode may include a plurality of third conductive films disposed to be spaced apart from one another in the first direction and a second direction, intersecting the first direction.

The light source unit may include a light source configured to emit light, and a polarization controller configured to control a polarization direction of light emitted from the light source. Light having the polarization direction, controlled by the polarization controller, may be irradiated onto the electro-optical crystal.

The detection apparatus may further include a first lens configured to condense light, irradiated from the light source unit onto the electro-optical crystal, to the electro-optical crystal.

The first lens may include a plurality of microlens.

The detection apparatus may further include a polarization separation unit configured to detect a light beam having a predetermined polarization direction, among light beams reflected from the reflection unit. The detection unit may be configured to detect the light beam having the predetermined polarization direction, detected by the polarization separation unit.

The polarization separation unit may be configured to detect a light beam for each polarization direction. The detection unit may be configured to detect a difference in intensity of light beams having different polarization directions.

The detection unit may include a second lens configured to image at least a portion of the electro-optical crystal onto the detection unit.

The detection apparatus may further include an optical path separation unit configured to separate a first optical path from the light source unit toward the reflection unit, and a second optical path from the reflection unit toward the detection unit from one another.

The electrode may have a predetermined degree of opacity with respect to light irradiated onto the electro-optical crystal.

The detection apparatus may further include an imaging unit configured to generate an image of the object and the electrode.

The detection apparatus may further include an alignment light source unit configured to emit alignment light having a predetermined wavelength range. At least a portion of the alignment light may be transmitted through the reflection unit and may reach the object. The alignment light, reaching the object, may be incident on the imaging unit.

According to aspects of the disclosure, there is provided a detection apparatus including an electro-optical crystal including a first surface opposing an object including micro pads spaced apart from one another, the object generating an electric field, and a second surface opposing the first surface, the electro-optical crystal having a refractive index changing according to the electric field, a light source unit configured to irradiate light onto the electro-optical crystal, a reflection unit between the first surface of the electro-optical crystal and the object, the reflection unit configured to reflect light transmitted through the electro-optical crystal, and an electrode structure on the second surface of the electro-optical crystal. The electrode structure may include a plurality of first conductive films on the second surface, the plurality of first conductive films spaced apart from one another, and electrode pads respectively connected to the plurality of first conductive films. The plurality of first conductive films may overlap regions in which the micro pads are spaced from one another, respectively.

The plurality of first conductive films may extend in a first direction. The electrode structure may further include second conductive films on the first conductive films, the second conductive films extending in a second direction, intersecting the first direction.

Each of the electrode pads may partially overlap the second surface of the electro-optical crystal. A portion of each of the electrode pads, not overlapping the second surface, may be exposed outside the electro-optical crystal.

A width of each of the plurality of first conductive films may have a range from about 1 μm to about 20 μm.

According to aspects of the disclosure, there is provided a detection apparatus including a device unit spaced apart from an object generating an electric field, a light source unit spaced apart from the device unit, the light source unit configured to emit a first light beam incident on the device unit, an optical path separation unit disposed between the light source unit and the device unit, the optical path separation unit configured to separate a path of second light beams reflected from the device unit, a polarization separation unit on which some light beams, among the second light beams reflected from the device unit and separated by the optical path separation unit, are incident, and a detection unit configured to detect some light beams, among the second light beams, incident on the polarization separation unit. The device unit may include an electro-optical crystal including a first surface opposing the object, and a second surface opposing the first surface, a reflective film on the first surface of the electro-optical crystal, the reflective film configured to reflect some light beams, among light beams incident on the device unit, and an electrode structure on the second surface of the electro-optical crystal. The electrode structure may include a plurality of conductive films on the second surface to be spaced apart from one another, and electrode pads respectively connected to and grounded to the plurality of conductive films.

### BRIEF DESCRIPTION OF THE DRAWINGS

The above and other aspects, features, and advantages of the disclosure will be more clearly understood from the following detailed description, taken in conjunction with the accompanying drawings, in which:

FIG. 1 is a schematic diagram illustrating an example of a configuration of a detection apparatus according to example embodiments of the disclosure;

FIG. 2 is a schematic diagram illustrating an example of a configuration of the measurement unit illustrated in FIG. 1;

FIG. 3 is a plan view illustrating an example of a configuration of the object illustrated in FIG. 2;

FIG. 4 is a schematic diagram illustrating an example of a configuration of a main portion of the measurement unit illustrated in FIG. 2;

FIG. 5 is a cross-sectional view illustrating an example of a configuration of the device unit illustrated in FIG. 4;

FIG. 6 is a diagram illustrating an example of a relationship between an electric field azimuth and a phase difference in the electro-optical crystal illustrated in FIG. 5;

FIG. 7 is a block diagram illustrating an example of a configuration of the information processing unit illustrated in FIG. 1;

FIG. 8 is a block diagram illustrating an example of a functional configuration of the information processing unit illustrated in FIG. 7;

FIG. 9 is a plan view illustrating an example of the electrode structure illustrated in FIG. 5;

FIG. 10A is a diagram illustrating a cross-section along line a-a of FIG. 9;

FIG. 10B is a diagram illustrating a cross-section along line b-b of FIG. 9;

FIG. 11A is a diagram illustrating an equipotential line in the cross-section illustrated in FIG. 10A;

FIG. 11B is a diagram illustrating an equipotential line in the cross-section illustrated in FIG. 10B;

FIG. 12 is a plan view illustrating an example of an electrode structure according to a comparative example;

FIG. 13 is a diagram illustrating an electric field detected in a detection apparatus having the electrode structure of each of FIGS. 9 and 12;

FIG. 14 is a schematic diagram illustrating an example of a configuration of a main portion of a detection apparatus according to a modification;

FIG. 15 is a plan view illustrating another example of the electrode structure illustrated in FIG. 9; and

FIG. 16 is a plan view illustrating still another example of the electrode structure illustrated in FIG. 9.

### DETAILED DESCRIPTION

Hereinafter, with reference to the accompanying drawings, example embodiments of the disclosure will be described in detail. In the following drawings, the same reference numerals indicate the same components, and sizes of components in the drawings are expressed at ratios different from those of actual components for clarity and convenience of description. The example embodiments described below are merely exemplary, and various modifications can be made based on such example embodiments.

In the following description, the terms “above” or “on” may include not only to a component that is directly on another component in a contact manner, but also to a component that is above another component in a non-contact manner.

As used herein, the singular forms “a,” “an,” and “the” are intended to include the plural forms as well, unless the context clearly indicates otherwise. In addition, when it is stated that a certain portion “includes” or “has” a certain component, unless explicitly stated otherwise, it does not exclude other components and may further include additional components.

In addition, the use of the term “the” and similar indicative terms applies to both the singular and the plural.

Regarding operations included in a method, unless a specific order is explicitly indicated or unless otherwise stated, the operations are performed in an appropriate order and are not limited to the order in which the operations are described. All examples or exemplary terms (for example, “such as”) are provided merely to describe the technical concept, and unless explicitly limited by the claims, the scope is not restricted by the examples or exemplary terms.

A technique in which a transparent electrode is disposed at a position opposing the object with the electro-optical crystal interposed therebetween has been proposed.

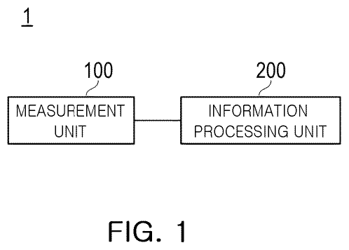

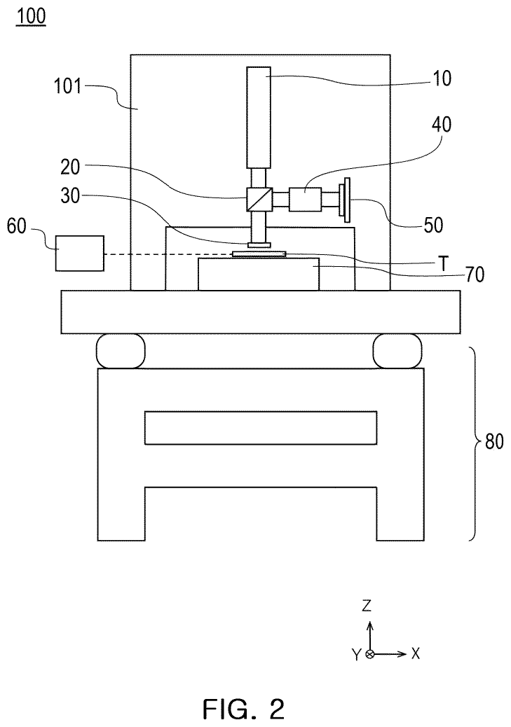

FIG. 1 illustrates an example of a schematic configuration of a detection apparatus 1 according to example embodiments of the disclosure. The detection apparatus 1 may include, for example, a measurement unit 100 and an information processing unit 200. The measurement unit 100 and the information processing unit 200 may be connected to one another, and signals may be transmitted and received between the measurement unit 100 and the information processing unit 200. The detection apparatus 1 may detect an electric field generated by an object (for example, an object T in FIG. 2 to be described below) using a reflective electro-optical probe (EOP) method. By using the EOP method, the electric field may be detected without destroying the object in a non-contact manner.

FIG. 2 schematically illustrates an example of a configuration of the measurement unit 100. The measurement unit 100 may include, for example, a light source unit 10, an optical path separation unit 20, a device unit 30, a polarization separation unit 40, a detection unit 50, a voltage supply unit 60, a stage 70, and a stand 80. For example, a light source unit 10, an optical path separation unit 20, a device unit 30, a polarization separation unit 40, a detection unit 50, and a stage 70 may be provided on the stand 80. Light, emitted from the light source unit 10, may be incident on the device unit 30 via the optical path separation unit 20. Light, incident on the device unit 30, may pass through the polarization separation unit 40 and is received by the detection unit 50. In the following description, a direction, parallel to a direction from the light source unit 10 toward the device unit 30, may be referred to as a Z-direction, a direction, perpendicular to the Z-direction, is referred to as an X-direction, and a direction, perpendicular to the Z-direction and an X-direction, may be referred to as a Y-direction.

The measurement unit 100 may include a cover 101 covering the light source unit 10, the optical path separation unit 20, the device unit 30, the polarization separation unit 40, the detection unit 50, and the stage 70. By providing the cover 101, temperature control during measurement may be easily performed.

An object T, generating an electric field, detected by the detection apparatus 1, may be disposed on one surface of the stage 70, for example. The one surface of the stage 70 is, for example, an X-Y plane. The one surface of the stage 70 may be configured to be movable in the X-direction, the Y-direction, and the Z-direction, for example. The stand 80, supporting the stage 70 or the like, may have a function of removing vibrations applied to the stage 70. The function of removing the vibrations of the stand 80 may include at least one of, for example, an active type and a passive type.

The voltage supply unit 60 may be electrically connected to the object T. The voltage supply unit 60 may supply a predetermined voltage to the object T. Accordingly, an electric field may be generated by the object T. The device unit 30 may be disposed at a position opposing the stage 70 with the object T interposed therebetween. The device unit 30 may be configured to be movable in the X-direction, the Y-direction, and the Z-direction.

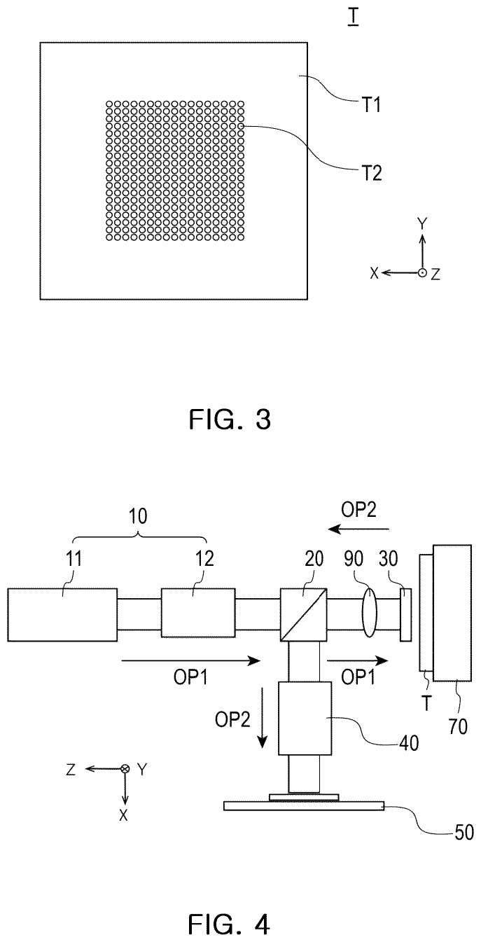

FIG. 3 illustrates an example of the object T. The object T may be, for example, a semiconductor device or the like. A semiconductor device may include, for example, an insulating material T1 having an X-Y plane and a plurality of micro pads T2 exposed to the X-Y plane from the insulating material T1. The micro pad T2 may function as, for example, a conductive portion connected to a wafer or a chip. The micro pad T2 may be formed of, for example, a conductive metal material such as copper. A size of the micro pad T2 may be, for example, about 10 μm to 100 μm in diameter. The plurality of micro pads T2 may be regularly disposed, for example. For example, the detection apparatus 1 may evaluate electrical characteristics of an internal circuit of the object T, and may detect an open-circuit state and a short-circuit state of each micro pad T2.

FIG. 4 illustrates an example of the measurement unit 100. The light source unit 10 may irradiate light toward the device unit 30. The light source unit 10 may include, for example, a light source 11 and a polarization controller 12.

The light source 11 may emit light having a predetermined wavelength range. The light source 11 may include, for example, a laser diode, and may emit laser light. The light source 11 may include a lamp. By using the light source 11 capable of stably emitting light, an electric field, generated by the object T, may be detected with higher precision. The wavelength range of light emitted from the light source 11 may be set, for example, in a wavelength range between a visible light region and an infrared region.

The polarization controller 12 may include, for example, a polarizer and a wavelength plate, and may control a polarization direction of light emitted from the light source 11. Light, passing through the polarization controller 12, may have a predetermined polarization direction. Light, emitted from the light source 11, may pass through the polarization controller 12, and may be incident on the optical path separation unit 20.

The optical path separation unit 20 may be provided between the light source unit 10 and the device unit 30. The optical path separation unit 20 may separate a first optical path OP1 and a second optical path OP2 from one another. The first optical path OP1 may be an optical path from the light source unit 10 toward the device unit 30. The first optical path OP1 may be transmitted through the optical path separation unit 20, for example. The first optical path OP1 may be provided in the Z-direction, for example. The second optical path OP2 may be an optical path from the device unit 30 to the detection unit 50. The second optical path OP2 may be bent from the Z-direction to the X-direction in the optical path separation unit 20, for example. The first optical path OP1 may be bent in the optical path separation unit 20, and the second optical path OP2 may be transmitted through the optical path separation unit 20. The optical path separation unit 20 may include, for example, a beam splitter.

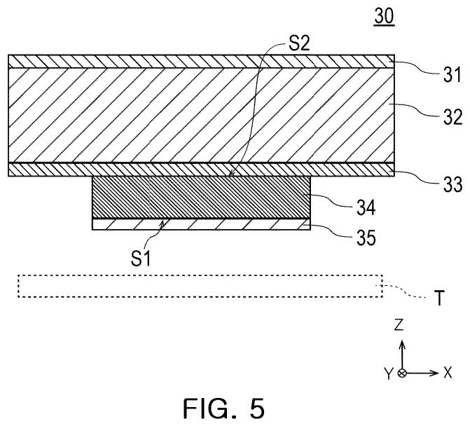

FIG. 5 illustrates an example of a specific configuration of the device unit 30. The device unit 30 may have an anti-reflective film 31, a support member 32, an electrode structure 33, an electro-optical crystal 34, and a reflective film 35 in the Z-direction, sequentially from a position close to the optical path separation unit 20. Here, the reflective film 35 may correspond to one specific example of a reflection unit of the disclosure.

For example, the anti-reflective film 31 may cover an X-Y plane of one side of the support member 32, and may prevent reflection of light from a surface of the support member 32. By providing the anti-reflective film 31, noise of light detected by the detection unit 50 may be suppressed.

The support member 32 may support the electrode structure 33, the electro-optical crystal 34, and the reflective film 35. The support member 32 may have high light transmittance with respect to light emitted from the light source unit 10. The support member 32 may include, for example, quartz (SiO₂).

The electrode structure 33 may be provided on an X-Y plane of the other side of the support member 32. That is, the electrode structure 33 may oppose the anti-reflective film 31 with the support member 32 interposed therebetween. The electrode structure 33 may serve to strengthen or amplify an electric field leaking from the object T to the electro-optical crystal 34. A detailed structure of the electrode structure 33 will be described below.

The electro-optical crystal 34 may be provided between the electrode structure 33 and the reflective film 35, and may have a first surface S1 and a second surface S2 opposing one another. The first surface S1 and the second surface S2 may be, for example, X-Y planes. The first surface S1 may oppose the object T. The reflective film 35 may be provided on the first surface S1. A distance between the first surface S1 and the object T may be, for example, about 10 μm to 200 μm. Depending on example embodiments, the first surface S1 and the object T may be in contact with one another with the reflective film 35 interposed therebetween. That is, the reflective film 35 may be in contact with the object T. The second surface S2 may oppose the object T with the first surface S1 interposed therebetween. That is, the second surface S2 may be spaced further apart from the object T than the first surface S1. The electrode structure 33 may be provided on the second surface S2.

The electro-optical crystal 34 may have a refractive index changing according to an applied electric field. The refractive index of the electro-optical crystal 34 may, for example, change anisotropically. In the detection apparatus 1, the anisotropic change of the refractive index of the electro-optical crystal 34 may be detected as a change in a polarization direction of light. The electro-optical crystal 34 may, for example, include lithium niobate (LiNbO₃). The electro-optical crystal 34 may include lithium tantalate (LiTaO₃), zinc telluride (ZnTe), or cadmium telluride (CdTe). In the electro-optical crystal 34, a magnitude of an electro-optical effect obtained may vary depending on a crystal orientation, a direction of the applied electric field, and a polarization direction of light.

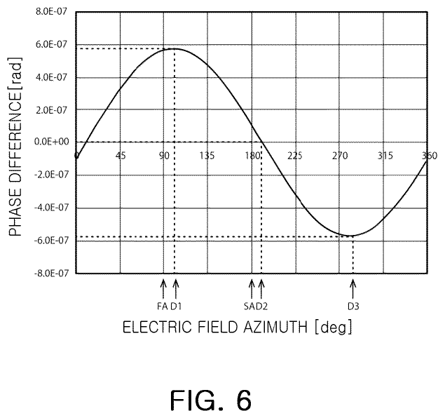

FIG. 6 illustrates an example of a relationship between a direction of an electric field applied to the electro-optical crystal 34 and a phase difference derived from the anisotropic refractive index change. Here, X-cut lithium niobate may be used as the electro-optical crystal 34, and a polarization direction may be tilted by 45° from a slow axis (SA) and a fast axis (FA), respectively. The phase difference may correspond to a magnitude of the electro-optical effect caused by the electro-optical crystal 34. From FIG. 6, it may be confirmed that the magnitude of the electro-optical effect changes in a sinusoidal shape according to the direction of the electric field. Here, when an electric field having a first direction D1, tilted by about 10° from the fast axis (FA) of the electro-Attorney optical crystal 34, is applied, the electro-optical crystal 34 may exhibit a maximum electro-optical effect. When an electric field having a second direction D2, tilted by 90° from the first direction D1, is applied, a phase difference caused by the electro-optical effect may not be exhibited in the electro-optical crystal 34. The second direction D2 may be a direction tilted by about 10° from the slow axis (SA) of the electro-optical crystal 34. For example, the Y-direction may correspond to the first direction D1, and the X-direction may correspond to the second direction D2.

A relationship between the direction of the electric field and the electro-optical effect may also be confirmed in other cut planes of the electro-optical crystal 34. In any cut plane, it may be confirmed that the electro-optical effect caused by the electro-optical crystal 34 changes in a sinusoidal shape according to the direction of the electric field.

A thickness (a size in the Z-direction) of the electro-optical crystal 34 may be, for example, about 1 μm to 200 μm. The thickness of the electro-optical crystal 34 may be set to about 100 μm or less, more preferably about 10 μm or less, such that the electric field of the object T may be detected with high spatial resolution. For example, the electric field of the object T may be detected with a resolution of about 10 μm. The detection apparatus 1 may be appropriately used for inspection of fine micro pads T2.

The reflective film 35 may be disposed between the first surface S1 of the electro-optical crystal 34 and the object T. The reflective film 35 may cover the first surface S1 of the electro-optical crystal 34. A gap may be provided between the reflective film 35 and the object T, or the reflective film 35 and the object T may be in contact with one another.

The reflective film 35 may reflect light, incident into the electro-optical crystal 34 from the second surface S2, with high reflectance. Light reflected by the reflective film 35 may propagate again through the electro-optical crystal 34 toward the optical path separation unit 20 from the second surface S2. The reflective film 35 may be formed of, for example, a dielectric multilayer film. Accordingly, the reflective film 35 may hardly affect an electric field generated by the object T, and the electric field generated by the object T may be efficiently detected.

Light, reaching the optical path separation unit 20 from the reflection film 35, may be incident on the polarization separation unit 40 along the second optical path OP2. The polarization separation unit 40 may be, for example, disposed between the optical path separation unit 20 and the detection unit 50. The polarization separation unit 40 may detect a light beam, among light beams incident on the polarization separation unit 40, having a predetermined polarization direction. The polarization separation unit 40 may separate incident light for each polarization direction, or may extract light having a predetermined polarization direction. The polarization separation unit 40 may include, for example, a polarizer and a wave plate. The polarization separation unit 40 may include, for example, a Wollaston prism, and may separate incident light for each polarization direction. The polarization separation unit 40 may include, for example, a linear polarizer, and may extract only light having a predetermined polarization direction.

Light, passing through the polarization separation unit 40, may be received by the detection unit 50. The detection unit 50 may detect intensity of light having a predetermined polarization. Light, affected by the electro-optical effect, may be detected by the detection unit 50. The detection unit 50 may include, for example, a photodiode, an avalanche amplifier, and a photomultiplier tube. The detection unit 50 may include a single pixel, or may include multiple pixels. When the detection unit 50 includes multiple pixels, light may be detected for each pixel. Accordingly, an electric field generated by the object T may be detected over a wider range within a short period of time. Alternatively, when the detection unit 50 includes a single pixel, the detection apparatus 1 may include a galvanometer mirror. Accordingly, a two-dimensional image, related to the electric field generated by the object T, may be generated.

The detection unit 50 may include a differential detector. The differential detector may detect a difference in intensity of light beams having different polarization directions, for example. By using the differential detector, an effect caused by stability of light emitted from the light source unit 10 on detection results may be suppressed.

The measurement unit 100 may further include one or more lens 90. The lens 90 may be disposed, for example, between the optical path separation unit 20 and the device unit 30. The lens 90 may be disposed on the first optical path OP1, and may collect light, transmitted through the optical path separation unit 20, onto the device unit 30, more specifically, onto the electro-optical crystal 34.

The lens 90 may be disposed on the second optical path OP2. In this case, the lens 90 may image at least a portion of the device unit 30, more specifically, at least a portion of the electro-optical crystal 34, onto the detection unit 50. The lens 90 may be disposed on each of the first optical path OP1 and the second optical path OP2, or a single lens 90 may be shared between the first optical path OP1 and the second optical path OP2. The measurement unit 100 may include a lens between the optical path separation unit 20 and the detection unit 50. Here, the lens 90 may correspond to a first lens and a second lens of the disclosure.

The information processing unit 200 may be, for example, a computer such as a personal computer (PC) or a tablet terminal. The information processing unit 200 may process signals detected by the detection unit 50, for example, while controlling operation of the measurement unit 100.

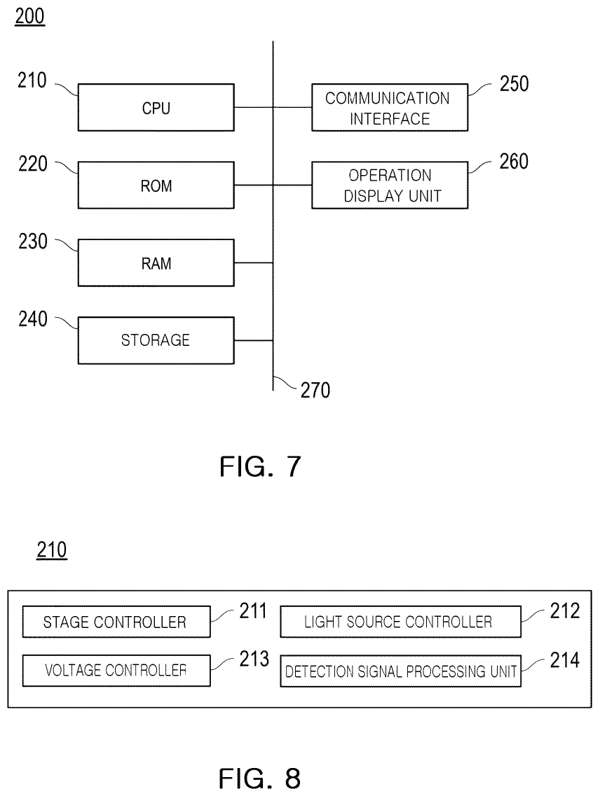

FIG. 7 is a block diagram illustrating an example of a configuration of the information processing unit 200. The information processing unit 200 may include, for example, a central processing unit (CPU) 210, a read only memory (ROM) 220, a random access memory (RAM) 230, a storage 240, a communication interface 250, and an operation display unit 260. Respective components may be communicatively connected to one another via a bus 270.

The CPU 210 may perform control of each component and various computations according to programs recorded in the ROM 220 and the storage 240. Specific functions of the CPU 210 will be described below.

The ROM 220 may store various programs and various pieces of data.

The RAM 230 may temporarily store programs or data as a working region.

The storage 240 may include various programs, including an operating system, and various pieces of data. The storage 240 may store programs for generating information on an electric field, generated by the object T, from optical signals detected by the detection unit 50. The storage 240 may store information on the object T or the like.

The communication interface 250 may serve as an interface for communication with other devices. A communication interface according to various wired or wireless standards may be used as the communication interface 250. The communication interface 250 may be used, for example, to receive signals from the measurement unit 100 or to transmit signals to the measurement unit 100.

The operation display unit 260 may include, for example, a display unit such as a liquid crystal display (LCD) or organic EL display and a touch panel including a touch sensor. A display unit displaying various types of information and an operation unit receiving various user inputs may be provided separately. In this case, the display unit may be implemented not only by the display but also by viewer software or a printer, and the operation unit may be implemented by a touch sensor, a pointing device such as a mouse, or a keyboard.

FIG. 8 is a block diagram illustrating a functional configuration of the information processing unit 200. The CPU 210 may read and process a program stored in the storage 240, such that the information processing unit 200 may function as a stage controller 211, a light source controller 212, a voltage controller 213, and a detection signal processing unit 214.

The stage controller 211 may generate a signal for driving the stage 70 and receive position information of the stage 70. The light source controller 212 may generate a signal for controlling light emitted from the light source unit 10 and receive operation information of the light source unit 10. The voltage controller 213 may generate a signal for controlling a voltage supplied by the voltage supply unit 60 to the object T and receive voltage information supplied by the voltage supply unit 60 to the object T. The signals may be transmitted and received between the information processing unit 200 and the measurement unit 100. The stage controller 211, the light source controller 212, and the voltage controller 213 may process one of generation and reception of the signals.

The detection signal processing unit 214 may receive a signal based on light detected by the detection unit 50, and may process the signal. The detection signal processing unit 214 may generate, for example, information on an electric field generated by the object T, based on the signal received from the detection unit 50. The information on the electric field generated by the object T may include, for example, information on an open-circuit state and a short-circuit state of each micro pad T2.

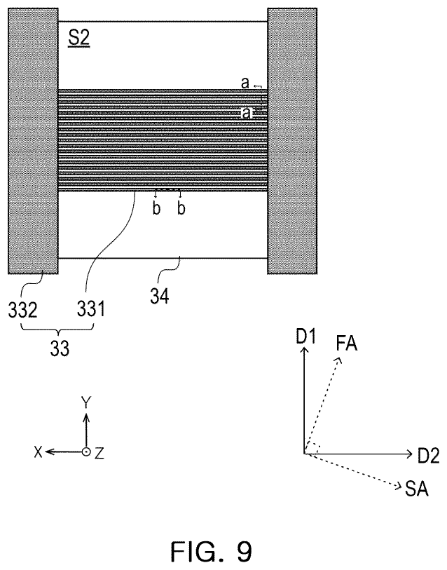

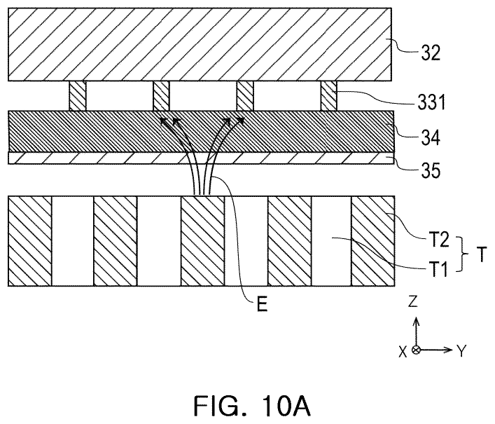

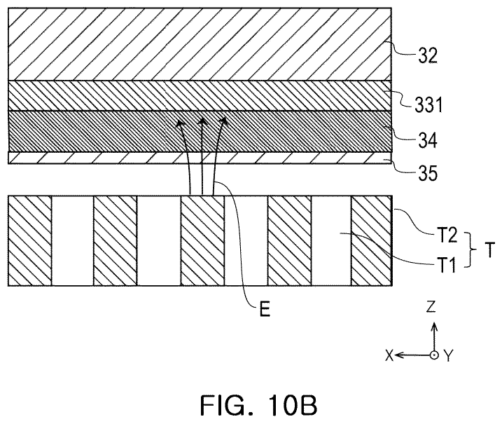

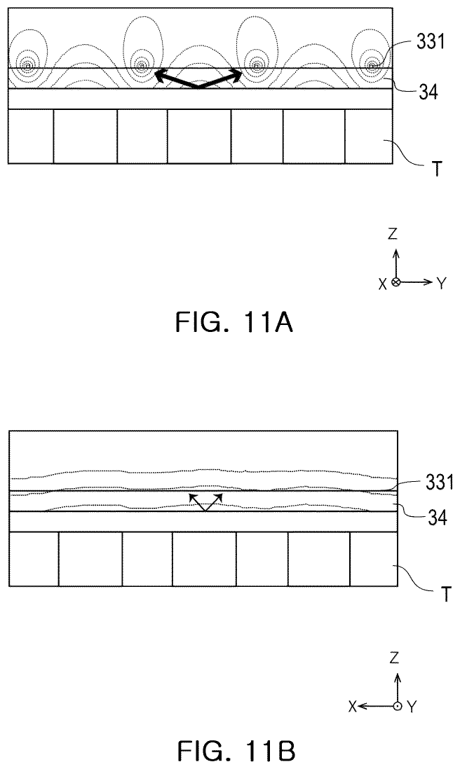

FIG. 9 illustrates an example of a plane (X-Y plane) configuration of the electrode structure 33. FIG. 10A illustrates a cross-section (Y-Z cross-section) along line a-a illustrated in FIG. 9, and FIG. 10B illustrates a cross-section (X-Z cross-section) along line b-b illustrated in FIG. 9. FIG. 11A illustrates an equipotential line in the Y-Z cross-section illustrated in FIG. 10A, and FIG. 11B illustrates an equipotential line in the X-Z cross-section illustrated in FIG. 10B. In FIG. 10A, FIG. 10B, FIG. 11A, and FIG. 11B, components around the electrode structure 33 are illustrated, together with the electrode structure 33.

The electrode structure 33 may include, for example, a conductive film 331 and an electrode pad 332. For example, the conductive film 331 and the electrode pad 332 may be provided to be in contact with the second surface S2 of the electro-optical crystal 34. Here, the conductive film 331 may correspond to one specific example of a first conductive film of the disclosure, and the conductive film 331 and the electrode pad 332 may correspond to one specific example of an electrode of the disclosure. The conductive film 331 and the electrode pad 332 may be electrically connected to one another, for example. The conductive film 331 and the electrode pad 332 may be connected to a predetermined potential through, for example, the electrode pad 332. The predetermined potential may be, for example, a ground potential. In order to secure an electrical connection path to the electrode pad 332, the electrode pad 332 may have a structure in which the electrode pad 332 is exposed outside the electro-optical crystal 34. The electrode pad 332 may partially overlap the electro-optical crystal 34. The electrode structure 33 may be provided to oppose the object T, such that an electric field may be generated between the electrode structure 33 and the object T. Accordingly, the electro-optical crystal 34 may more effectively exhibit an electro-optical effect.

In the example embodiments, the conductive film 331 and the electrode pad 332 may cover a portion of the second surface S2 of the electro-optical crystal 34. In other words, the second surface S2 of the electro-optical crystal 34 may have a portion not covered with the conductive film 331 and the electrode pad 332. Accordingly, a signal amount based on the electro-optical effect may be increased.

The electrode structure 33 may include, for example, a plurality of conductive films 331. The plurality of conductive films 331 may be disposed, for example, on a central portion of the second surface S2, and may respectively extend in an X-direction, parallel to the second surface S2. The plurality of conductive films 331 may be disposed in a Y-direction, parallel to the second surface S2, with a gap interposed therebetween. For example, the plurality of conductive films 331 may be disposed to be spaced apart from one another in the Y-direction, parallel to the second surface S2. The gap between the plurality of conductive films 331 in the Y-direction may correspond to a portion of the second surface S2, not covered with the conductive film 331 and the electrode pad 332. Here, the Y-direction may correspond to one specific example of a first direction of the disclosure, and the X-direction may correspond to one specific example of a second direction of the disclosure.

A width (size in the Y-direction) and a length (size in the X-direction) of each of the plurality of conductive films 331 may be substantially the same, for example. The width of each of the plurality of conductive films 331 may be in a range of about 1 μm to about 20 μm, for example. The plurality of conductive films 331 may be disposed in parallel in the Y-direction, for example, with substantially uniform gaps therebetween. That is, the plurality of conductive films 331 may be disposed in a line-and-space structure. A pitch of the plurality of conductive films 331 may be preferably the same as a pitch of the micro pad T2 of the object T. For example, the conductive film 331 may be disposed at a position corresponding to a space between adjacent micro pads T2 (FIG. 10A). For example, each of the plurality of conductive films 331 may not overlap the micro pad T2 in a Z-direction, and may overlap a space between the micro pads T2 in the Z-direction. Accordingly, an electric field of an element in the Y-direction may be more effectively enhanced.

As described, the electrode structure 33 may have gaps disposed in parallel in the Y-direction. Thus, when a predetermined voltage is applied to the object T, an electric field E including a large number of elements in the Y-direction together with elements in the Z-direction may be generated (FIG. 10A and FIG. 11A). The Y-direction may correspond, for example, to a first direction D1 of the electro-optical crystal 34. That is, when the electric field E in the first direction D1 is applied to the electro-optical crystal 34, the electro-optical crystal 34 may exhibit a maximum electro-optical effect. The number of elements in the X-direction included in the electric field E may be smaller than the number of elements in the Y-direction (FIG. 10B and FIG. 11B). The X-direction may correspond, for example, to a second direction D2 of the electro-optical crystal 34.

The electrode pad 332 may be disposed, for example, on an end of the second surface S2 in the X-direction, and may extend in the Y-direction. Both ends of each of the plurality of conductive films 331 in the X-direction may be connected to the electrode pad 332, for example. An area of an X-Y plane of the electrode pad 332 may be larger than an area of an X-Y plane of each conductive film 331. For example, an external terminal may be connected to the electrode pad 332.

The conductive film 331 and the electrode pad 332 may be formed of, for example, a transparent conductive film such as an indium-tin oxide (ITO). Alternatively, the conductive film 331 and the electrode pad 332, covering only a portion of the second surface S2, may not have high light transmittance with respect to light emitted from the light source unit 10. In other words, the conductive film 331 and the electrode pad 332 may have a predetermined degree of opacity with respect to light emitted from the light source unit 10. Here, the predetermined degree of opacity may refer to, for example, a degree of opacity higher than that of the transparent conductive film. The conductive film 331 and the electrode pad 332 may include a metal material such as copper (Cu) or gold (Au). The conductive film 331 and the electrode pad 332, covering only a portion of the second surface S2, may not require high light transmittance, thereby improving a degree of freedom in design.

The device unit 30 may be formed as follows, for example. First, an anti-reflective film 31 may be formed on one surface of the support member 32, and then the electrode structure 33 may be adhered to the other surface opposite to the one surface. The electrode structure 33 may be formed by using, for example, a metal processing treatment. By using the metal processing treatment, the electrode structure 33 may be formed through a simple process. After forming a conductive film on the other surface of the support member 32, the electrode structure 33 may also be formed by etching the conductive film. Through etching of the conductive film, a more detailed pattern of the electrode structure 33 may be formed.

Subsequently, the second surface S2 of the electro-optical crystal 34 may be adhered to the electrode structure 33. After the electrode structure 33 is formed on the second surface S2 of the electro-optical crystal 34, the electro-optical crystal 34 may be bonded to the support member 32. The electrode structure 33 may be formed on the second surface S2 of the electro-optical crystal 34, alignment accuracy between a pattern of the electrode structure 33 and a crystal direction of the electro-optical crystal 34 may be improved.

Subsequently, a reflective film 35 may be formed on the first surface S1 of the electro-optical crystal 34. Before the reflective film 35 is formed, a thickness of the electro-optical crystal 34 may be reduced. Alternatively, after the reflective film 35 is formed on the first surface S1 of the electro-optical crystal 34, the second surface S2 of the electro-optical crystal 34 may be bonded to the electrode structure 33. Alternatively, the electrode structure 33 may be formed on the second surface S2 of the electro-optical crystal 34, and the reflective film 35 may be formed on the first surface S1, and then the electro-optical crystal 34 may be bonded to the support member 32.

First, based on a signal from the information processing unit 200, the stage 70 may be driven, and a predetermined voltage may be supplied to the object T from the voltage supply unit 60. Subsequently, based on a signal from the information processing unit 200, the light source unit 10 may emit light.

Light, emitted from the light source unit 10, may propagate to the optical path separation unit 20, and may be incident on the device unit 30 along the first optical path OP1 from the optical path separation unit 20. In the device unit 30, the light may sequentially pass through the anti-reflective film 31, the support member 32, the electrode structure 33, and the electro-optical crystal 34, and may be reflected by the reflective film 35. In the electro-optical crystal 34, an anisotropic refractive index change may occur due to an electric field leaked from the object T. A phase of light incident on the electro-optical crystal 34 according to a polarization direction may be changed depending on the refractive index change. That is, a polarization direction of light may be changed.

Light, having the polarization direction changed described above, may be reflected by the reflective film 35, and may be incident on the optical path separation unit 20. Light, incident on the optical path separation unit 20 from the reflective film 35, may pass through the polarization separation unit 40 along the second optical path OP2, and may be received by the detection unit 50. A signal, based on light detected by the detection unit 50, may be transmitted to the information processing unit 200. The information processing unit 200 may generate, based on the signal, information on an electric field generated by the object T.

In the detection apparatus 1 of the example embodiments, the conductive film 331 and the electrode pad 332 may cover only a portion of the second surface S2 of the electro-optical crystal 34, such that a predetermined pattern of the conductive film 331 may be formed. Accordingly, among electric fields E generated between the object T and the electrode structure 33, an electric field of an element in a first-direction D1 (Y-direction) may be selectively enhanced. The first direction D1 may be, for example, a direction in which the electro-optical crystal 34 exhibits a maximum electro-optical effect, thereby increasing a signal amount based on the electro-optical effect. Hereinafter, such an operational effect will be described.

An EOP method may include a transmission type and a reflection type. By using the reflection-type EOP method, spatial resolution may be increased. To this end, in an object having a fine pattern such as a semiconductor device, the reflection-type EOP method may be preferably used.

In the reflection-type EOP method, a thickness of an electro-optical crystal may be reduced, thereby suppressing diffusion of an electric field in the electro-optical crystal, and inspecting an object with higher spatial resolution. When the thickness of the electro-optical crystal is reduced, a length of an optical path in the electro-optical crystal may be reduced, and an electro-optical effect may hardly affect detected light, which may be caused by a gap between the object and the electro-optical crystal. As a result, a signal based on the electro-optical effect may not be detected in a sufficient amount.

In the reflection-type EOP method, an electrode may be provided on the second surface of the electro-optical crystal, an electric field may be generated between the object and the electrode, and a signal amount based on the electro-optical effect may be increased. However, depending on an arrangement of the electrode, the signal amount may not be sufficiently increased.

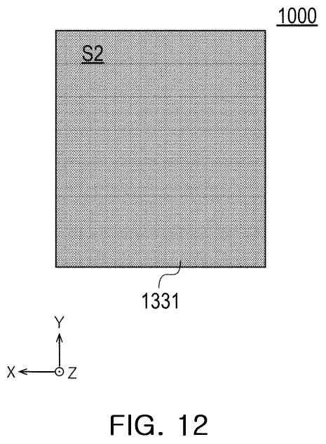

FIG. 12 illustrates a plane (X-Y plane) configuration of an electrode structure 1000 according to a comparative example. In the electrode structure 1000, a conductive film 1331 may cover an entire second surface S2 of an electro-optical crystal 34. In other words, in the conductive film 1331, gaps disposed in parallel in the Y-direction may not be provided. To this end, in the electrode structure 1000, among electric fields generated between an object and the electrode structure 1000, an intensity of an electric field of an element in the Y-direction may not be selectively enhanced.

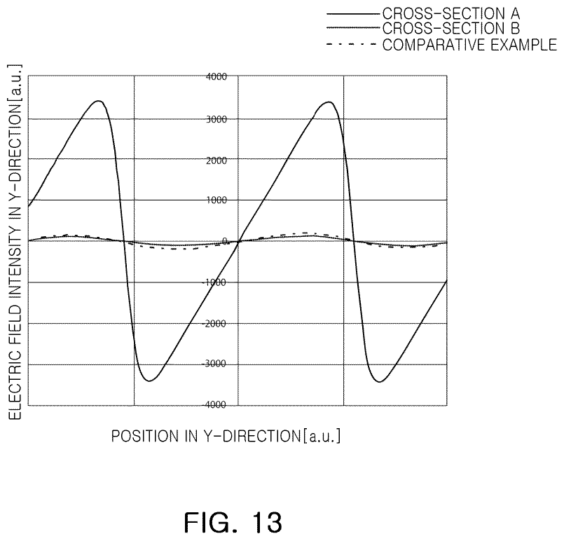

FIG. 13 illustrates simulation results of the electrode structure 33 and the electrode structure 1000. A vertical axis in FIG. 13 may represent an intensity of an electric field of an element in the Y-direction applied to the electro-optical crystal 34 from the object T, and a horizontal axis in FIG. 13 may represent a position in the Y-direction. As compared to the electrode structure 1000, in the electrode structure 33, it may be confirmed that the electric field of the element in the Y-direction is enhanced. For example, when a thickness of the electro-optical crystal 34 is about 10 μm, in the electrode structure 33, the electric field of the element in the Y-direction may be about 28 times stronger than that in the electrode structure 1000.

As described, in the detection apparatus 1, the conductive film 331 and the electrode pad 332 may cover only a portion of the second surface S2 of the electro-optical crystal 34, such that, among electric fields E generated between the object T and the electrode structure 33, an electric field of an element in the first direction D1 (Y-direction) may be selectively enhanced, thereby efficiently enhancing an electro-optical effect, and increasing a signal amount based on the electro-optical effect.

Hereinafter, a detection apparatus 1 according to a modification will be described. Hereinafter, in order to avoid repeated description, a detailed description about a configuration the same as that of the detection apparatus 1 according to the above example embodiments will be omitted.

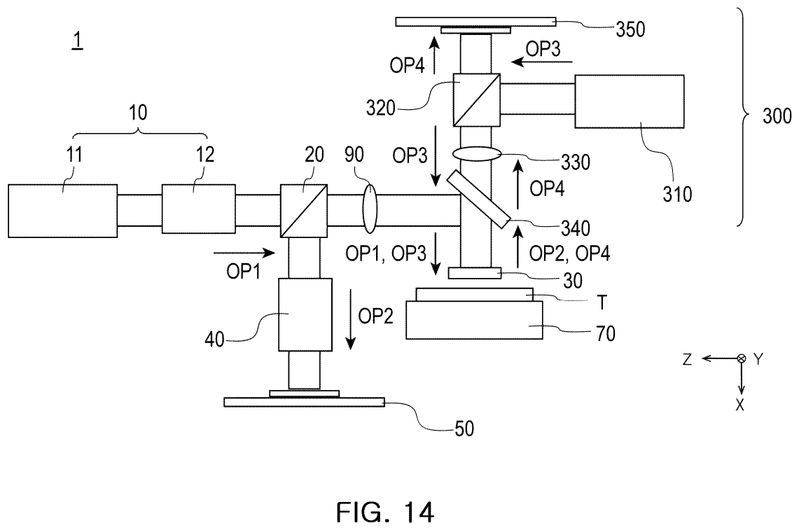

FIG. 14 illustrates an example of the detection apparatus 1 according to the modification. The detection apparatus 1 may include an alignment unit 300. Except for the alignment unit 300, the detection apparatus 1 according to the modification may have a configuration the same as that of the detection apparatus 1 described in the above example embodiments.

The alignment unit 300 may be used to confirm a region of an object T in which an electric field is being detected, that is, a measurement region of the object T. The alignment unit 300 may, for example, generate a two-dimensional image representing a relative positional relationship between the object T and an electrode structure 33, and may present the measurement region of the object T to a user.

The alignment unit 300 may include, for example, a light source unit 310, a first optical path separation unit 320, a lens 330, a second optical path separation unit 340, and an imaging unit 350. Here, the light source unit 310 may correspond to one specific example of an alignment light source unit of the disclosure.

The light source unit 310 may emit alignment light having a predetermined wavelength range. The alignment light may be incident on a device unit 30 along a third optical path OP3 from the light source unit 310. The third optical path OP3 may be an optical path extending from the light source unit 310 toward the device unit 30, and may extend from the light source unit 310 toward the device unit 30 while sequentially passing through the first optical path separation unit 320, the lens 330, and the second optical path separation unit 340. A portion of the alignment light, incident on the device unit 30, may be reflected by the electrode structure 33. At least another portion of the alignment light incident on the device unit 30 may be transmitted through the device unit 30, that is, may be transmitted through a reflective film 35 to reach the object T. In other words, the wavelength range of the alignment light may be selected from a wavelength range in which light may be transmitted through the reflective film 35. Light, reflected by the electrode structure 33 and light reaching the object T, may be incident on the imaging unit 350 along a fourth optical path OP4. The fourth optical path OP4 may be an optical path extending from the device unit 30 toward the imaging unit 350, and may extend from the device unit 30 toward the imaging unit 350 while sequentially passing through the second optical path separation unit 340, the lens 330, and the first optical path separation unit 320.

The first optical path separation unit 320 may separate the third optical path OP3 and the fourth optical path OP4 from one another. The first optical path separation unit 320 may include, for example, a beam splitter.

The lens 330 may be disposed, for example, between the first optical path separation unit 320 and the second optical path separation unit 340. The lens 330 may be provided, for example, on the fourth optical path OP4, and may image the device unit 30 and the object T onto the imaging unit 350.

The second optical path separation unit 340 may separate the second optical path OP2 and the fourth optical path OP4 from one another. The second optical path separation unit 340 may include, for example, a dichroic mirror.

The imaging unit 350 may receive light incident along the fourth optical path OP4. The imaging unit 350 may generate a two-dimensional image of the object T and the electrode structure 33, based on the received light. The imaging unit 350 may include, for example, a camera.

Also in the detection apparatus 1 according to the modification, as described in the above example embodiments, a conductive film 331 and an electrode pad 332 may cover only a portion of a second surface S2 of an electro-optical crystal 34, such that, among electric fields E generated by the object T, an electric field of an element in a first direction D1 (Y-direction) may be selectively enhanced, thereby efficiently enhancing an electro-optical effect, and increasing a signal amount based on the electro-optical effect.

In addition, since the detection apparatus 1 includes the alignment unit 300, a user may easily confirm a measurement region of the object T.

The above-described configuration of the detection apparatus 1 is presented to describe main features of the above-described example embodiments, and is not limited to the described configuration. Various modifications may be made within the scope of the claims. In addition, configurations included in a general detection apparatus are not excluded.

For example, in the above example embodiments, an example has been described in which a plurality of conductive films 331 are disposed in the first direction D1 with a gap interposed therebetween, but the plurality of conductive films 331 may also be disposed in a direction deviated from the first direction D1 with a gap interposed therebetween.

In addition, in the above example embodiments, an example has been described in which the electrode structure 33 has a line-and-space structure as a predetermined pattern, but the electrode structure 33 may also have another predetermined pattern.

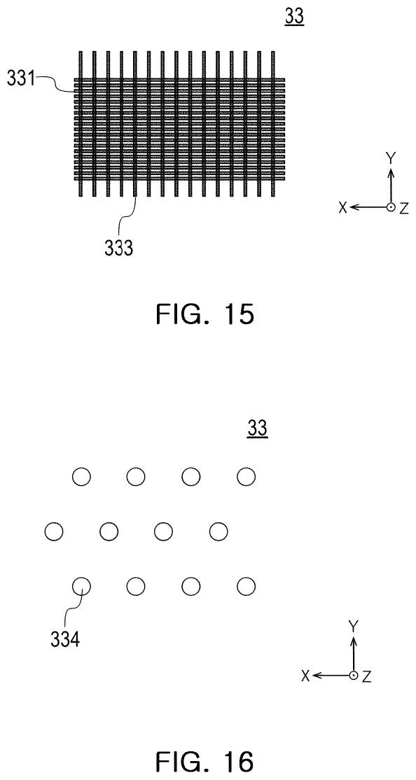

FIGS. 15 and 16 illustrate other examples of the pattern of the electrode structure 33. The electrode structure 33 may include, for example, conductive films 331 and 333 disposed in a lattice shape. A plurality of conductive films 333 may respectively extend in a Y-direction, and may be disposed with a gap interposed therebetween in an X-direction (FIG. 15). Here, the conductive film 333 may correspond to one specific example of a second conductive film of the electrode structure 33 of the disclosure.

The electrode structure 33 may further include, for example, conductive films 334 disposed in a point shape or a dot shape. A plurality of conductive films 334 may be respectively disposed with a gap interposed therebetween in the X-direction and Y-direction, (FIG. 16). Here, the conductive film 334 may correspond to one specific example of a third conductive film of the electrode structure 33 of the disclosure.

In addition, the electrode structure 33 may not have a regular pattern.

In addition, the lens 90 may include a plurality of microlens. In this case, each of the plurality of microlens may selectively collect light onto a portion of the electro-optical crystal 34 in which a strong electric field E is generated, thereby more effectively increasing a signal amount based on the electro-optical effect.

A detection method for detecting an electric field generated by an object according to example embodiments may include irradiating light onto an electro-optical crystal having a first surface opposing the object, the electro-optical crystal having a refractive index changing according to the electric field, reflecting, by a reflection unit provided between the first surface of the electro-optical crystal and the object, light transmitted through the electro-optical crystal, and detecting light reflected from the reflection unit. A portion of a second surface of the electro-optical crystal, opposing the object with the first surface interposed therebetween, may be covered by an electrode.

According to example embodiments of the present disclosure, in a detection apparatus and a detection method according to the disclosure, an electrode may cover only a portion of a second surface of an electro-optical crystal, such that an electric field in a predetermined direction, among electric fields generated between an object and the electrode, may be selectively enhanced. The predetermined direction may be, for example, a direction in which the electro-optical effect occurs more efficiently. Accordingly, a signal amount may be increased based on the electro-optical effect.

While example embodiments have been shown and described above, it will be apparent to those skilled in the art that modifications and variations could be made without departing from the scope of the disclosure as defined by the appended claims.

What is claimed is:

1. A detection apparatus for detecting an electric field generated by an object, the detection apparatus comprising:
an electro-optical crystal including a first surface opposing the object and a second surface opposing the object with the first surface therebetween, the electro-optical crystal having a refractive index changing according to the electric field;
a light source unit configured to irradiate light onto the electro-optical crystal;
a reflection unit between the first surface of the electro-optical crystal and the object, the reflection unit configured to reflect light transmitted through the electro-optical crystal;
a detection unit configured to detect light reflected by the reflection unit; and
an electrode covering a portion of the second surface of the electro-optical crystal.

2. The detection apparatus of claim 1, wherein:
the electrode includes a plurality of first conductive films, and the plurality of first conductive films are disposed with a gap interposed therebetween in a first direction, substantially parallel to the second surface.

3. The detection apparatus of claim 2, wherein each of the plurality of first conductive films extends in a second direction, intersecting the first direction.

4. The detection apparatus of claim 3, wherein:
the electrode further includes a plurality of second conductive films extending substantially in the first direction, and
the plurality of second conductive films are disposed with a gap interposed therebetween in the second direction.

5. The detection apparatus of claim 1, wherein the electrode includes a plurality of third conductive films disposed to be spaced apart from one another in a first direction and a second direction, intersecting the first direction.

6. The detection apparatus of claim 1, wherein:
the light source unit includes a light source configured to emit light, and a polarization controller configured to control a polarization direction of light emitted from the light source, and
light having the polarization direction, controlled by the polarization controller, is irradiated onto the electro-optical crystal.

7. The detection apparatus of claim 1, further comprising:
a first lens configured to condense light, irradiated from the light source unit onto the electro-optical crystal, to the electro-optical crystal.

8. The detection apparatus of claim 7, wherein the first lens includes a plurality of microlens.

9. The detection apparatus of claim 1, further comprising:
a polarization separation unit configured to detect a light beam having a predetermined polarization direction, among light beams reflected from the reflection unit,
wherein the detection unit is configured to detect the light beam having the predetermined polarization direction, detected by the polarization separation unit.

10. The detection apparatus of claim 9, wherein:
the polarization separation unit is configured to detect a light beam for each polarization direction, and
the detection unit is configured to detect a difference in intensity of light beams having different polarization directions.

11. The detection apparatus of claim 1, wherein the detection unit includes a second lens configured to image at least a portion of the electro-optical crystal onto the detection unit.

12. The detection apparatus of claim 1, further comprising:
an optical path separation unit configured to separate a first optical path from the light source unit toward the reflection unit, and a second optical path from the reflection unit toward the detection unit from one another.

13. The detection apparatus of claim 1, wherein the electrode has a predetermined degree of opacity with respect to light irradiated onto the electro-optical crystal.

14. The detection apparatus of claim 1, further comprising:
an imaging unit configured to generate an image of the object and the electrode.

15. The detection apparatus of claim 14, further comprising:
an alignment light source unit configured to emit alignment light having a predetermined wavelength range,
wherein at least a portion of the alignment light is transmitted through the reflection unit and reaches the object, and
the alignment light, reaching the object, is incident on the imaging unit.

16. A detection apparatus comprising:
an electro-optical crystal including a first surface opposing an object including micro pads spaced apart from one another, the object generating an electric field, and a second surface opposing the first surface, the electro-optical crystal having a refractive index changing according to the electric field;
a light source unit configured to irradiate light onto the electro-optical crystal;
a reflection unit between the first surface of the electro-optical crystal and the object, the reflection unit configured to reflect light transmitted through the electro-optical crystal; and
an electrode structure on the second surface of the electro-optical crystal,
wherein the electrode structure includes:
a plurality of first conductive films on the second surface, the plurality of first conductive films spaced apart from one another, and electrode pads respectively connected to the plurality of first conductive films, and
the plurality of first conductive films overlap regions in which the micro pads are spaced from one another, respectively.

17. The detection apparatus of claim 16, wherein:
the plurality of first conductive films extend in a first direction, and
the electrode structure further includes second conductive films on the first conductive films, the second conductive films extending in a second direction, intersecting the first direction.

18. The detection apparatus of claim 16, wherein:
each of the electrode pads partially overlaps the second surface of the electro-optical crystal, and
a portion of each of the electrode pads, not overlapping the second surface, is exposed outside the electro-optical crystal.

19. The detection apparatus of claim 16, wherein a width of each of the plurality of first conductive films has a range from about 1 μm to about 20 μm.

20. A detection apparatus comprising:
a device unit spaced apart from an object generating an electric field;
a light source unit spaced apart from the device unit, the light source unit configured to emit a first light beam incident on the device unit;
an optical path separation unit disposed between the light source unit and the device unit, the optical path separation unit configured to separate a path of second light beams reflected from the device unit;
a polarization separation unit on which some light beams, among the second light beams reflected from the device unit and separated by the optical path separation unit, are incident; and
a detection unit configured to detect some light beams, among the second light beams, incident on the polarization separation unit,
wherein the device unit includes:
an electro-optical crystal including a first surface opposing the object, and a second surface opposing the first surface;
a reflective film on the first surface of the electro-optical crystal, the reflective film configured to reflect some light beams, among light beams incident on the device unit; and
an electrode structure on the second surface of the electro-optical crystal, and
the electrode structure includes a plurality of conductive films on the second surface to be spaced apart from one another, and electrode pads respectively connected to and grounded to the plurality of conductive films.
